(19) United States
(12) Patent Application Publication
(10) Pub. No.: US 2023/0402334 A1
(43) Pub. Date: Dec. 14, 2023

(54) SEMICONDUCTOR DEVICE

(71) Applicant: FUJI ELECTRIC CO., LTD., Kawasaki-shi (JP)

(72) Inventor: Toshio DENTA, Matsumoto-city (JP)

(73) Assignee: FUJI ELECTRIC CO., LTD., Kawasaki-shi (JP)

(21) Appl. No.: 18/305,577

(22) Filed: Apr. 24, 2023

(30) Foreign Application Priority Data
Jun. 13, 2022 (JP) 2022-094823

(51) Int. Cl. H01L 23/053; H01L 23/31; H01L 23/32

(52) U.S. Cl. CPC H01L 23/053; H01L 23/3121; H01L 23/32; H01L 2224/48137; H01L 2224/48175; H01L 24/48

(57) ABSTRACT

A frame body includes reinforcing portions. The reinforcing portions are each provided in the region formed by a side frame and one of a pair of attachment frames in plan view. Each reinforcing portion is in contact with the side frame, the one of the pair of attachment frames, and the corner at which the side frame and one of the pair of attachment frames are joined.

### CROSS-REFERENCE TO RELATED APPLICATION

This application is based upon and claims the benefit of priority of the prior Japanese Patent Application No. 2022-094823, filed on Jun. 13, 2022, the entire contents of which are incorporated herein by reference.

### BACKGROUND OF THE INVENTION

### 1. Field of the Invention

The embodiments discussed herein relate to a semiconductor device.

### 2. Background of the Related Art

Semiconductor devices include power devices and are used as power conversion devices. For example, power devices are semiconductor elements such as insulated gate bipolar transistors (IGBTs) and power metal-oxide-semiconductor field-effect transistors (MOSFETs). A semiconductor device that includes semiconductor chips including such semiconductor elements and a substrate on which the semiconductor chips are disposed is formed by accommodating these components in a case and sealing with a sealing material. In addition, in the semiconductor device, the substrate protrudes from the rear surface of the case.

A screw hole is formed at the center of each of the opposite short sides of the case included in such a semiconductor device. For example, the semiconductor device is disposed on a heat sink, and screws are inserted into the screw holes and are engaged with the heat sink. By doing so, the semiconductor device is attached to the heat sink.

Please see, for example, Japanese Laid-open Patent Publication No. 2020-184591.

The substrate protrudes from the rear surface of the semiconductor device. When the semiconductor device is placed on the heat sink, a gap is formed between the rear surface of the case and the heat sink. Then, when the screws passing through the screw holes of the case are engaged with the heat sink in this situation, the screws tighten the screw holes, stress is generated and concentrated around the screw holes, and thus cracks may occur. The case is damaged due to the cracks, which leads in a reduction in the reliability of the semiconductor device.

### SUMMARY OF THE INVENTION

According to one aspect, there is provided a semiconductor device, including: a semiconductor chip; a substrate including the semiconductor chip on a front surface thereof; a case that is rectangular in a plan view of the semiconductor device and includes first to fourth side frames in this order that are attached to the substrate so that the first to fourth side frames are respectively disposed at respective ones of four sides of the substrate to form a housing region therein; and a sealing material filling the housing region to seal the front surface of the substrate and the semiconductor chip, wherein the case further includes a first attachment portion, to which a screw is attached, on a side of the first side frame facing the housing region, the first attachment portion includes a pair of first attachment frames extending toward an inside of the housing region in parallel to the second side frame and the fourth side frame in the plan view, and a first connecting frame connecting ends of the pair of first attachment frames at the inside of the housing region, the pair of first attachment frames connecting to the first side frame and facing each other with an opening therebetween penetrating through the first side frame in the plan view, and the case further includes a first reinforcing portion that is provided in a first region formed by the first side frame and one of the pair of first attachment frames in the plan view, the first reinforcing portion being in contact with the first side frame, the one of the pair of first attachment frames, and a first corner at which the first side frame and the one of the pair of first attachment frames are joined in the plan view.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a first side view of the semiconductor device according to the first embodiment;

FIG. 3 is a second side view of the semiconductor device according to the first embodiment;

FIG. 4 is a plan view of the inside of the semiconductor device according to the first embodiment;

FIG. 5 is a sectional view of the semiconductor device according to the first embodiment;

FIG. 6 is a plan view of an attachment portion of the semiconductor device according to the first embodiment;

FIG. 7 is a plan view of a semiconductor device according to a reference example;

FIG. 8 is a graph representing the tightening torque of a screw with respect to a protruding amount of a substrate of the semiconductor device;

FIG. 9 is a plan view of an attachment portion of the semiconductor device according to the first embodiment (variation 1-1);

FIG. 10 is a plan view of an attachment portion of the semiconductor device according to the first embodiment (variation 1-2); and

FIG. 11 is a plan view of an attachment portion of a semiconductor device according to a second embodiment.

### DETAILED DESCRIPTION OF THE INVENTION

Hereinafter, embodiments will be described with reference to the accompanying drawings. In the following description, the terms “front surface” and “upper surface” refer to an X-Y surface facing up (in the +Z direction) in a semiconductor device 1 of the drawings. Similarly, the term “up” refers to an upward direction (the +Z direction) in the semiconductor device 1 of the drawings. The terms “rear surface” and “lower surface” refer to an X-Y surface facing down (in the −Z direction) in the semiconductor device 1 of the drawings. Similarly, the term “down” refers to a downward direction (the −Z direction) in the semiconductor device 1 of the drawings. The same directionality applies to other drawings, as appropriate. The terms “front surface,” “upper surface,” “up,” “rear surface,” “lower surface,” “down,” and “side surface” are used for convenience to describe relative positional relationships, and do not limit the technical ideas of the embodiments. For example, the terms “up” and “down” are not always related to the vertical directions to the ground. That is, the “up” and “down” directions are not limited to the gravity direction. In addition, in the following description, the term “main component” refers to a component contained at a volume ratio of 80 vol % or more. The expression “being approximately the same” may permit an error range of ±10%. In addition, the expressions “being perpendicular” and “being parallel” may permit an error range of ±10%.

### First Embodiment

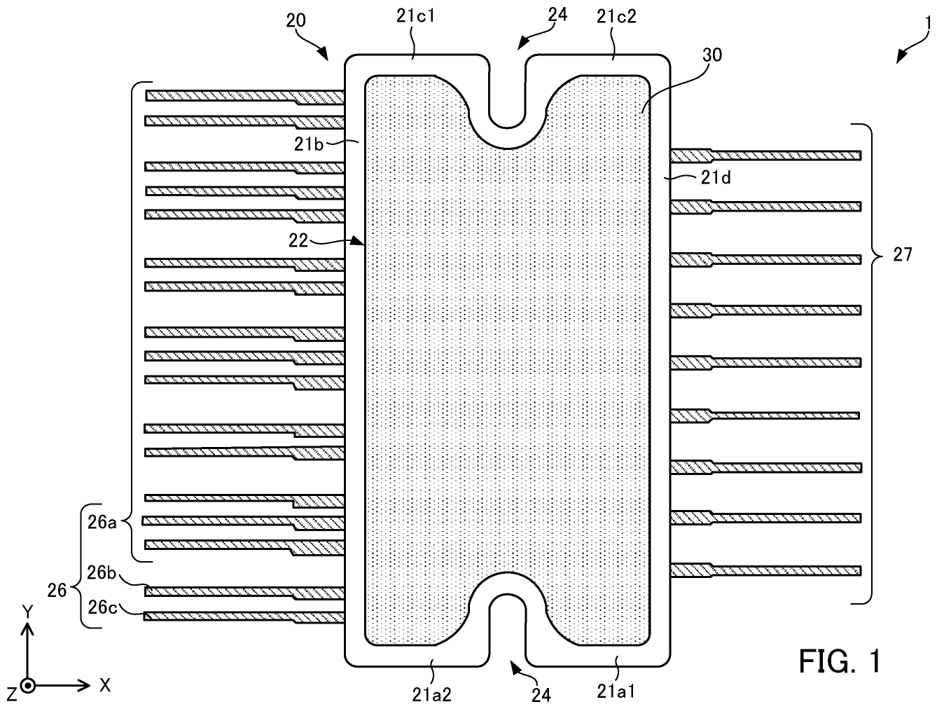

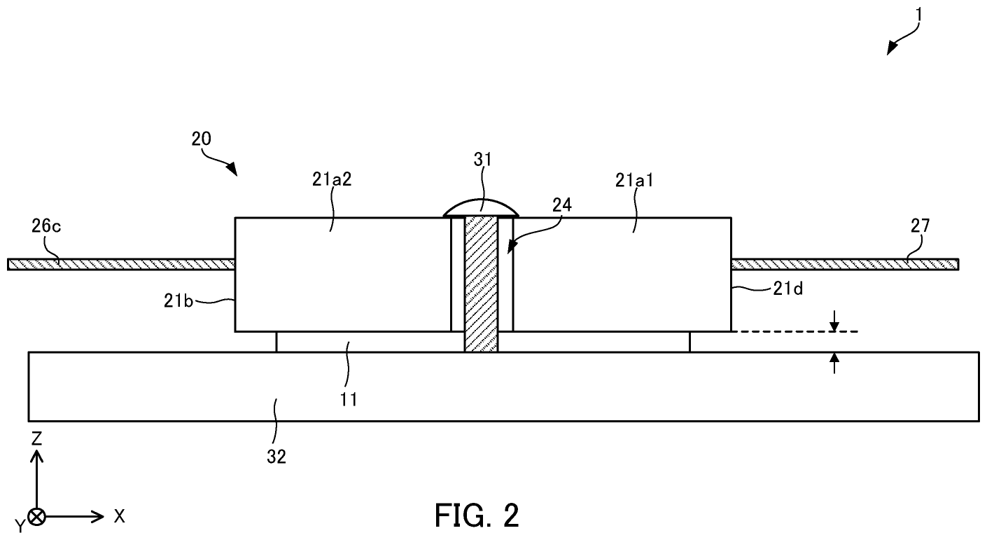

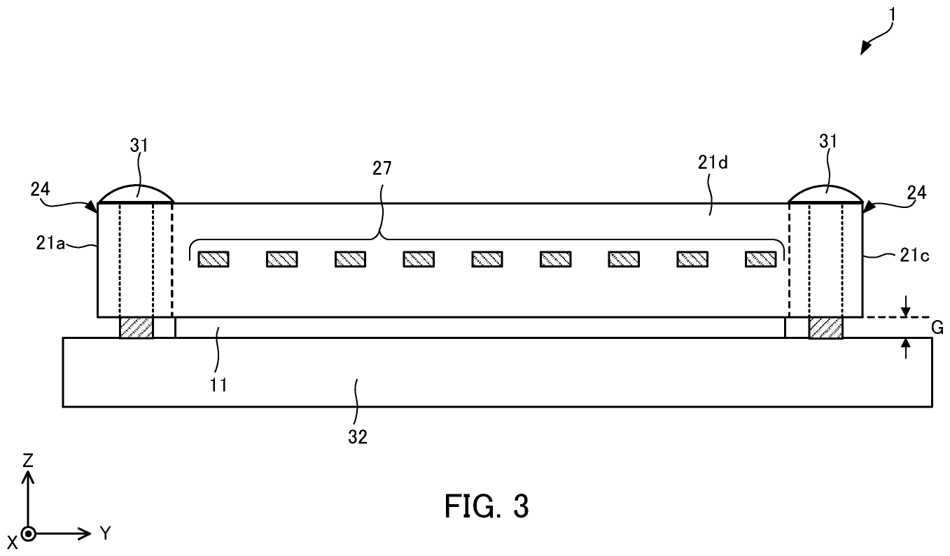

The appearance of a semiconductor device according to a first embodiment will be described with reference to FIGS. 1 to 3. FIG. 1 is a plan view of the semiconductor device according to the first embodiment, and FIGS. 2 and 3 are side views of the semiconductor device according to the first embodiment. Note that FIG. 1 is a plan view of the semiconductor device 1 to which a heat dissipation base plate 32 is not attached. FIG. 2 illustrates the semiconductor device 1 having the heat dissipation base plate 32 attached thereto. In addition, FIG. 2 is a side view of the semiconductor device of FIG. 1 as viewed in the Y direction, and FIG. 3 is a side view of the semiconductor device of FIG. 1 as viewed in the −X direction.

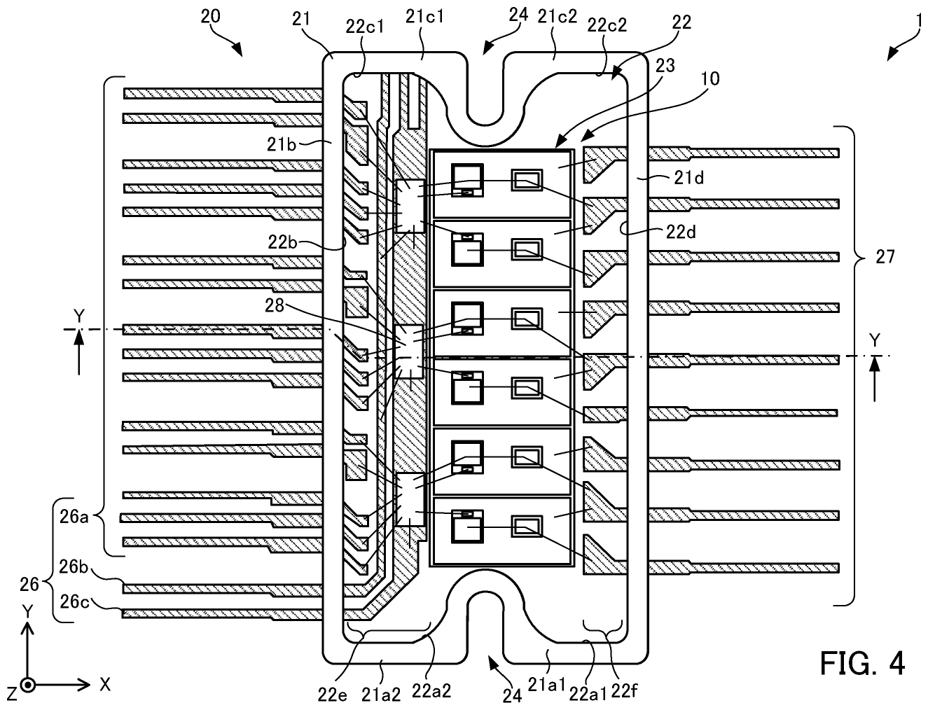

The semiconductor device 1 includes a case 20 filled with a sealing material 30. The case 20 includes a frame body 21, control terminals 26, and main current terminals 27. The frame body 21 has a rectangular frame shape in plan view, and has side frames 21a1 and 21a2, a side frame 21b, side frames 21c1 and 21c2, and a side frame 21d that surround the four sides of an upper housing space 22 (housing region) in order. In this connection, the side frames 21a1 and 21a2 have an attachment portion 24 therebetween, as will be described later, and are flush with each other in plan view. Similarly, the side frames 21c1 and 21c2 have another attachment portion 24 therebetween and are flush with each other in plan view. The side frames 21a1 and 21a2 and side frames 21c1 and 21c2 correspond to the short sides of the case 20. The side frame 21b and side frame 21d correspond to the long sides of the case 20. In addition, the inner walls 22a1 and 22a2 of the side frames 21a1 and 21a2, the inner wall 22b of the side frame 21b, the inner walls 22c1 and 22c2 of the side frames 21c1 and 21c2, and the inner wall 22d of the side frame 21d face the housing region and are in contact with the sealing material 30 (see FIG. 4).

The side frames 21a2, 21b, and 21c1 are integrally connected to one another. The side frames 21c2, 21d, and 21a1 are integrally connected to one another. The joints between them form the four corners of the case 20. The corners may have rounded surfaces. Likewise, the joints between the inner walls 22a2, 22b, and 22c1 and the joints between the inner walls 22c2, 22d, and 22a1 may have rounded surfaces.

In addition, the frame body 21 has the attachment portion 24 to which a screw is attached, on the side of the side frames 21a1 and 21a2 facing the upper housing space 22. Similarly, the frame body 21 has the other attachment portion 24 on the side of the side frames 21c1 and 21c2 facing the upper housing space 22. These attachment portions 24 are U-shaped in plan view, and are formed between the side frames 21a1 and 21a2 and between the side frames 21c1 and 21c2, and enter (project into) the upper housing space 22 from between the side frames 21a1 and 21a2 and from between the side frames 21c1 and 21c2. The attachment portions 24 will be described in detail later. For example, as illustrated in FIGS. 2 and 3, the attachment portions 24 connect the front surface and the rear surface of the frame body 21. Therefore, the inner surfaces (facing outside) of the attachment portions 24 are curved. In addition, a heat dissipation plate 11 protrudes from the bottom surface of the frame body 21, as will be described in detail later.

A plurality of control terminals 26 extend from the side frame 21b of the frame body 21 in the −X direction. In this connection, the plurality of control terminals 26 include a plurality of control terminals 26a to 26c. A plurality of main current terminals 27 extend from the side frame 21d of the frame body 21 in the +X direction. The plurality of control terminals 26 and the plurality of main current terminals 27 are made of a metal with high electrical conductivity as a main component. Examples of the metal here include copper and a copper alloy. Plating may be performed on the plurality of control terminals 26 and the plurality of main current terminals 27. Examples of the plating material used here include nickel, a nickel-phosphorus alloy, a nickel-boron alloy, silver, and a silver alloy. In this connection, the attachment of the plurality of control terminals 26 and the plurality of main current terminals 27 to the frame body 21 will be described in detail later.

The above case 20 is formed by integrally forming the frame body 21 with the plurality of control terminals 26 and the plurality of main current terminals 27. The material of the frame body 21 contains a thermoplastic resin as a main component. Examples of the thermoplastic resin include a polyphenylene sulfide resin, a polybutylene terephthalate resin, a polybutylene succinate resin, a polyamide resin, and an acrylonitrile butadiene styrene resin.

On the other hand, the sealing material 30 may be a thermosetting resin. Examples of the thermosetting resin include an epoxy resin, a phenolic resin, a maleimide resin, and a polyester resin. The thermosetting resin is preferably an epoxy resin. In addition, a filler may be added to the sealing material 30. The filler is made of ceramic materials with electrical insulation and high thermal conductivity.

The heat dissipation base plate 32 is attached to the rear surface of the semiconductor device 1. The semiconductor device 1 is mounted on the front surface of the heat dissipation base plate 32, and screws 31 are inserted into the attachment portions 24. The screws 31 passing through the attachment portions 24 are engaged with the heat dissipation base plate 32. The heat dissipation base plate 32 is a flat plate. The front surface of the heat dissipation base plate 32 may be substantially level. In addition, a plurality of fins may be integrally formed on the rear surface of the heat dissipation base plate 32. The heat dissipation base plate 32 is made of a metal with high thermal conductivity as a main component. Examples of the metal here include copper, aluminum, and an alloy containing at least one of these. Plating may be performed to improve the corrosion resistance of the heat dissipation base plate 32. Examples of the plating material used here include nickel, a nickel-phosphorus alloy, and a nickel-boron alloy. In this connection, in place of the heat dissipation base plate 32, a cooling device that achieves cooling performance using cold water may be used.

In addition, a bonding material (not illustrated) is applied between the semiconductor device 1 and the heat dissipation base plate 32. The bonding material may be a brazing material or a thermal interface material. The brazing material contains, as a main component, at least one of an aluminum alloy, a titanium alloy, a magnesium alloy, a zirconium alloy, and a silicon alloy, for example. The thermal interface material is an adhesive such as an elastomer sheet, a room temperature vulcanization (RTV) rubber, a gel, or a phase change material, for example. The use of such a brazing material or thermal interface material for the attachment to the heat dissipation base plate 32 enables the semiconductor device 1 to improve its heat dissipation performance.

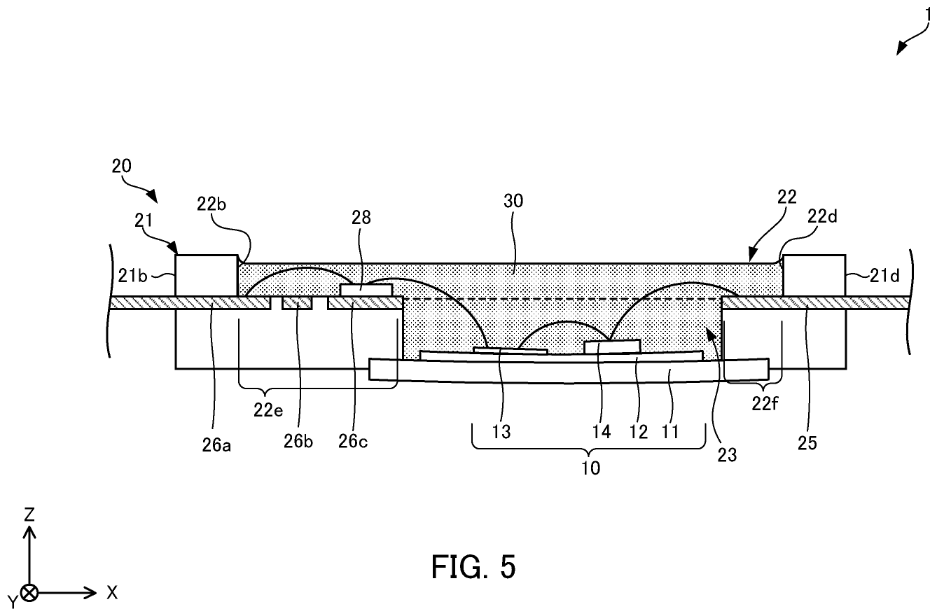

The following describes the details of the frame body 21 of the case 20 and components accommodated in the frame body 21, with reference to FIGS. 4 and 5. FIG. 4 is a plan view of the inside of the semiconductor device according to the first embodiment. FIG. 5 is a sectional view of the semiconductor device according to the first embodiment. In this connection, FIG. 4 is a plan view of the semiconductor device 1 without the sealing material FIG. 5 is a sectional view taken along a dash-dotted line Y-Y of FIG. 4.

As described earlier, the frame body 21 of the semiconductor device 1 has the side frames 21a1 and 21a2, side frame 21b, side frames 21c1 and 21c2, and side frame 21d that surround the four sides of the housing region (the upper housing space 22 in plan view) in order. The housing region includes the upper housing space 22 and a lower housing space 23. The upper housing space 22 is surrounded on its four sides by the upper portions (located above the broken line of FIG. 5 in the +Z direction) of the side frames 21a1 and 21a2, side frame 21b, side frames 21c1 and 21c2, side frame 21d, and attachment portions 24. The lower housing space 23 is surrounded on its four sides by the lower portions (located under the broken line of FIG. 5 in the −Z direction) of the side frames 21a1 and 21a2, side frame 21b, side frames 21c1 and 21c2, side frame 21d, and attachment portions 24. The side frames 21b and 21d each have a step projecting toward the lower housing space 23. Therefore, in plan view, the opening area of the lower housing space 23 is smaller in size than that of the upper housing space 22.

Each of the plurality of control terminals 26 has one end extending from the side frame 21b in the −X direction and the other end placed on the step (a control terminal region 22e) of the side frame 21b. A plurality of control terminals 26a among the plurality of control terminals 26 each form a straight line in plan view. The plurality of control terminals 26a are arranged in a line (in the ±Y directions) along the side frame 21b on the control terminal region 22e. Each of the plurality of control terminals 26a has one end extending from the side frame 21b to outside (in the −X direction) and the other end placed on the control terminal region 22e.

The control terminals 26b and 26c among the plurality of control terminals 26 each have an L-shape in plan view. The extending portions of the control terminals 26b and 26c extending in the ±Y directions are located inside the control terminals 26a (in the +X direction) on the control terminal region 22e. The extending portions of the control terminals 26b and 26c extending in the ±X directions extend from the side frame 21b to the outside (in the −X direction) in parallel to the plurality of control terminals 26a.

The plurality of main current terminals 27 each have one end extending from the side frame 21d in the +X direction and the other end placed on the step (a main current terminal region 22f) of the side frame 21d. The plurality of main current terminals 27 each form a straight line in plan view. The plurality of main current terminals 27 are arranged in a line (in the ±Y directions) along the side frame 21d on the main current terminal region 22f.

In addition, as illustrated in FIGS. 4 and 5, the frame body 21 accommodates a semiconductor unit 10 and control integrated circuits (ICs) 28 therein. The semiconductor unit 10 includes six sets each including a first semiconductor chip 13 and a second semiconductor chip 14. In addition, the semiconductor unit 10 includes six circuit wiring patterns 12 each having disposed thereon one set of first semiconductor chip 13 and second semiconductor chip 14, and a heat dissipation plate 11 having these circuit wiring patterns 12 formed on the front surface thereof.

In this connection, in the above semiconductor unit 10, six sets each including a first semiconductor chip 13, a second semiconductor chip 14, and a circuit wiring pattern 12 having the first semiconductor chip 13 and second semiconductor chip 14 disposed on the front surface thereof are arranged in parallel to the long side of the heat dissipation plate 11 on the heat dissipation plate 11, for example. The total three control ICs 28 are provided, each for two sets of first semiconductor chip 13 and second semiconductor chip 14. In the case where a component or the like is provided in plurality in the present embodiment, one of these will be described, unless otherwise described.

The first semiconductor chips 13 include switching elements. A switching element is an IGBT or a power MOSFET, for example. In the case where a first semiconductor chip 13 is an IGBT, the first semiconductor chip 13 has a collector electrode serving as a main electrode on the rear surface thereof, and has a gate electrode serving as a control electrode and an emitter electrode serving as a main electrode on the front surface thereof. In the case where a first semiconductor chip 13 is a power MOSFET, the first semiconductor chip 13 has a drain electrode serving as a main electrode on the rear surface thereof, and has a gate electrode serving as a control electrode and a source electrode serving as a main electrode on the front surface thereof. The rear surfaces of the first semiconductor chips 13 are bonded to the circuit wiring patterns 12 via a bonding material (not illustrated). As the bonding material, a solder or a sintered metal is used in the present embodiment. The solder is a lead-free solder containing a predetermined alloy as a main component. For example, the predetermined alloy is any one of a tin-silver alloy, a tin-zinc alloy, and a tin-antimony alloy. The solder may contain an additive such as copper, bismuth, indium, nickel, germanium, cobalt, or silicon, for example. As the sintered metal, aluminum or copper is used, for example.

The second semiconductor chips 14 include diode elements. A diode element is a free wheeling diode (FWD) such as a Schottky barrier diode (SBD) or a P-intrinsic-N (PiN) diode, for example. A second semiconductor chip 14 of this type has an output electrode (a cathode electrode) serving as a main electrode on the rear surface thereof, and has an input electrode (an anode electrode) serving as a main electrode on the front surface thereof. The rear surfaces of the second semiconductor chips 14 are bonded to the circuit wiring patterns 12 using the above-stated bonding material. These first and second semiconductor chips 13 and 14 may be made of silicon, silicon carbide, or gallium nitride, as appropriate.

Alternatively, in place of the first and second semiconductor chips 13 and 14, reverse-conducting (RC)—IGBT switching elements may be used. An RC-IGBT is formed by integrating an IGBT and a free wheeling diode (FWD) into one chip. A semiconductor chip including such an element has a gate electrode serving a control electrode and an emitter electrode serving as an output electrode, which is a main electrode, on the front surface thereof, and also has a collector electrode serving as an input electrode, which is a main electrode, on the rear surface thereof. As with the RC-IGBTs, power MOSFETs in which a body diode functions as an FWD may be used, in place of the first and second semiconductor chips 13 and 14. A power MOSFET that is usable here is made of silicon carbide as a main component, for example.

The circuit wiring patterns 12 are made of a metal with high electrical conductivity as a main component. Examples of the metal here include copper and a copper alloy. Plating may be performed on the circuit wiring patterns 12. Examples of the plating material used here include nickel, a nickel-phosphorus alloy, a nickel-boron alloy, silver, and a silver alloy. By performing plating on the circuit wiring patterns 12, their corrosion resistance and bonding property are improved.

The heat dissipation plate 11 includes a metal plate and an insulating layer formed on the front surface of the metal plate. The metal plate is made of a metal with high thermal conductivity as a main component. Examples of the metal here include aluminum, iron, silver, copper, and an alloy containing at least one of these. In addition, to improve the corrosion resistance and bonding property, plating may be performed. Examples of the plating material used here include nickel, a nickel-phosphorus alloy, a nickel-boron alloy, silver, and a silver alloy. The opening edge of the lower housing space 23 of the frame body 21 is attached to the outer periphery of the heat dissipation plate 11 using an adhesive. In addition, the circuit wiring patterns 12 are formed on the front surface of the insulating layer. This insulating layer may be an organic insulating layer that is made of a combination of an insulating resin with low thermal resistance such as an epoxy resin or liquid crystal polymer, and a material with high thermal conductivity such as boron nitride, aluminum oxide, or silicon oxide. Alternatively, the insulating layer may be an inorganic insulating layer that is made of ceramic materials with high thermal conductivity, such as aluminum oxide, aluminum nitride, or silicon nitride.

In addition, as the circuit wiring patterns 12 and heat dissipation plate 11, a direct copper bond (DCB) substrate or active metal brazed (AMB) substrate may be used, in which a copper foil is bonded to both surfaces of an inorganic insulating layer made of aluminum oxide, aluminum nitride, or silicon nitride. In this connection, the shapes, positions, and quantity of the circuit wiring patterns 12 and the positions and quantity of the first semiconductor chips 13 and second semiconductor chips 14 in the semiconductor unit 10 configured as above are illustrated as an example in FIGS. 4 and 5, and may be appropriately set according to design and others.

The control ICs 28 are respectively bonded at three positions on the control terminal 26c via a solder (not illustrated). In addition, as illustrated in FIG. 4, the main current terminals 27, circuit wiring patterns 12, first and second semiconductor chips 13 and 14, and control terminals 26 are directly connected with wires, where appropriate. The wires are made of a material with high electrical conductivity as a main component. Examples of the material here include gold, silver, copper, aluminum, and an alloy containing at least one of these.

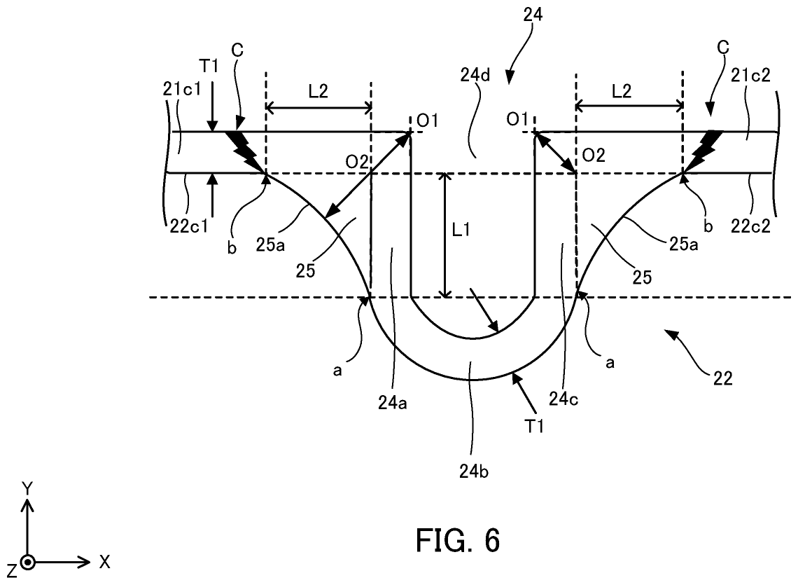

The following describes the attachment portions 24 provided in the frame body 21 in detail with reference to FIG. 6. FIG. 6 is a plan view of an attachment portion of the semiconductor device according to the first embodiment. In this connection, the attachment portion 24 illustrated in FIG. 6 is formed between the side frames 21c1 and 21c2 in the frame body 21. The following describes this attachment portion 24 formed between the side frames 21c1 and 21c2. The attachment portion 24 formed between the side frames 21a1 and 21a2 in the frame body 21 has the same configuration as illustrated in FIG. 6.

As described earlier, the attachment portion 24 is formed on the side of the side frames 21c1 and 21c2 facing the upper housing space 22. This attachment portion 24 includes a pair of attachment frames 24a and 24c, a connecting frame 24b, and reinforcing portions 25.

The paired attachment frames 24a and 24c respectively connect to the side frames 21c1 and 21c2, face each other with an opening 24d penetrating through the side frames 21c1 and 21c2 therebetween in plan view, and extend toward the inside of the upper housing space 22 in parallel to the side frames 21b and 21d (see FIG. 4). The width (in the ±X directions) of the opening 24d is set so as to allow the diameter of a screw 31 to fit therein. The paired attachment frames 24a and 24c may be formed such as to be substantially perpendicular to the side frames 21c1 and 21c2. In this connection, the corners of the side frames 21c1 and 21c2 facing the opening 24d are taken as points 01 in FIG. 6. FIG. 6 illustrates a broken line passing through points 02 that are the connecting places (corners) of each side frame 21c1 and 21c2 and the corresponding one of the paired attachment frames 24a and 24c.

The connecting frame 24b connects ends of the paired attachment frames 24a and 24c closest to the inside of the upper housing space 22. In plan view, the connecting frame 24b forms a partial ring shape (an arc shape), which is like a shape obtained by cutting a true circle. The connecting frame 24b may be formed in a semi-ring shape (a semicircular shape), provided that the connecting frame 24b is able to connect the attachment frames 24a and 24c smoothly. That is, the surfaces of the connecting frame 24b facing the upper housing space 22 and the opening 24d are curved so as to project toward the upper housing space 22. In this connection, FIG. 6 illustrates a broken line passing through points a that are the connecting places of each of the paired attachment frames 24a and 24c and the connecting frame 24b. That is, the length of the paired attachment frames 24a and 24c is a length L1 from the point 02 to the point a. In addition, the side frames 21c1 and 21c2, attachment frames 24a and 24c, and connecting frame 24b have a uniform and equal thickness T1.

A reinforcing portion 25 is provided in a region formed (in an L shape) by the side frame 21c1 and attachment frame 24a in plan view. Similarly, another reinforcing portion 25 is provided in a region formed (in an L shape) by the side frame 21c2 and attachment frame 24c in plan view. Each reinforcing portion 25 is in contact with the point 02 at the corner at which a side frame 21c1 or 21c2 and the corresponding one of the paired attachment frames 24a and 24c are joined, the side frame 21c1 or 21c2, and the corresponding attachment frame 24a or 24c.

Referring to FIG. 6, one end point (at the lower side (in the −Y direction) of FIG. 6) of each reinforcing portion 25 reaches the point a of the corresponding one of the paired attachment frames 24a and 24c. That is, the reinforcing portions 25 are in overall contact with the paired attachment frames 24a and 24c, respectively. In this connection, the one end point of each reinforcing portion 25 may be located between the point 02 and the point a, preferably located close to the point a, and more preferably located at the point a. FIG. 6 illustrates the case where the one end point of each reinforcing portion is located at the point a. The resistance to the tightening of the screws 31, to be described later, increases as the one end point of each reinforcing portion 25 is located closer to the point a.

The other end points (at the left and right sides (in the ±X directions) of FIG. 6) of the reinforcing portions 25 reach the respective points b of the side frames 21c1 and 21c2. That is, the portions of the reinforcing portions 25 in contact with the side frames 21c1 and 21c2 have a length L2. In addition, each reinforcing portion 25 has a reinforcing surface 25a connecting one end point (point a) and the other end point (point b) of the reinforcing portion 25 in plan view. Each reinforcing surface 25a has a rounded surface that is convex toward the point 02 in plan view. The points a at the connecting places of the surface of the connecting frame 24b facing the upper housing space 22 and each reinforcing surface 25a are infection points. Similarly, the points b at the connecting places of each side frame 21c1 and 21c2 and the corresponding reinforcing surface are infection points.

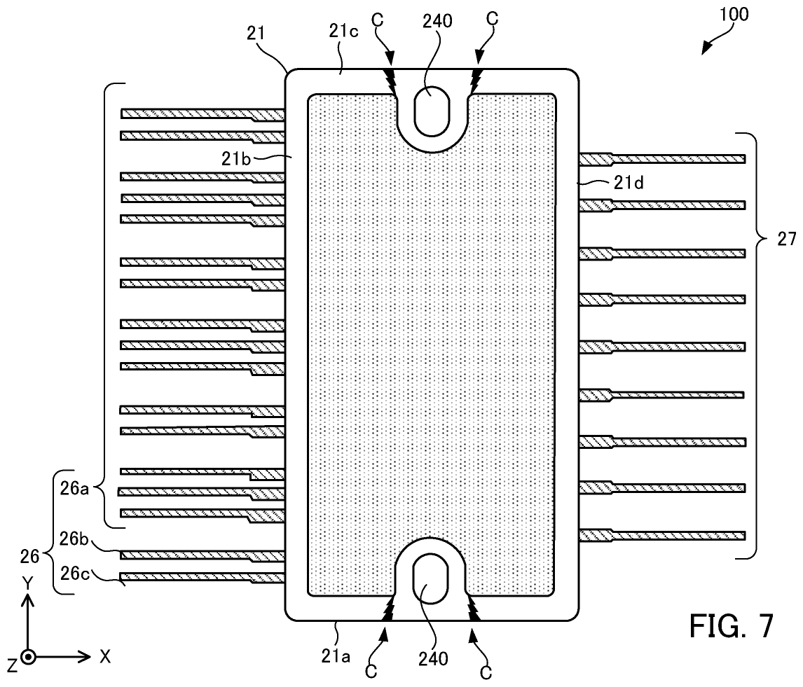

The following describes a semiconductor device 100 according to a reference example with reference to FIG. 7. FIG. 7 is a plan view of the semiconductor device according to the reference example. As illustrated in FIG. 7, the semiconductor device 100 of the reference example does not have openings penetrating through the side frames 21a and 21c of the frame body 21 corresponding to the short sides thereof. That is, unlike the side frames 21a1 and 21a2 and side frames 21c1 and 21c2 of the semiconductor device 1, the side frames 21a and 21c each form a continuous straight line. The semiconductor device 100 has attachment portions 240 on the sides of the side frames 21a and 21c where the upper housing space 22 is provided in the frame body 21. That is, each attachment portion 240 has a continuous ring shape. In this connection, the semiconductor device 100 of the reference example has the same configuration as the semiconductor device 1, except the attachment portions 240. Therefore, a heat dissipation plate 11 protrudes from the rear surface of the semiconductor device 100 as well.

The above semiconductor device 100 is attached to a heat dissipation base plate 32, as illustrated in FIGS. 2 and 3. That is, screws 31 are inserted into the attachment portions 240 formed in the side frames 21a and 21c of the semiconductor device 100, and are engaged with the heat dissipation base plate 32. When the screws 31 are tightened to the heat dissipation base plate 32, stress is generated at the forming places (corresponding to the points 02 in FIG. 6) of the attachment portions 240 in the side frames 21a and 21c, because the heat dissipation plate 11 protrudes from the rear surface of the semiconductor device 100. Then, when the tightening torque increases, cracks C occur. In addition, the frame body 21 and sealing material 30 of the semiconductor device 100 are made of different materials. That is, the frame body 21 and sealing material 30 have different thermal expansion coefficients. Therefore, when the semiconductor device 100 operates and thus heat is generated, thermal stress is generated between the frame body 21 and the sealing material 30. Especially, the thermal stress is concentrated at corners such as the forming places (corresponding to the points 02 in FIG. 6) of the attachment portions 240 in the side frames 21a and 21c. If the cracks C have occurred at these places, the cracks C extend due to the thermal stress, which leads to damaging the frame body 21.

In addition, the semiconductor device 100 is fastened to the heat dissipation base plate 32 by the screws 31 passing through the attachment portions 240. In order to remove the semiconductor device 100 from the heat dissipation base plate 32, the screws 31 need to be removed from the attachment portions 240 completely, because the attachment portions 240 have a ring shape. Therefore, it needs time and effort to remove the semiconductor device 100 from the heat dissipation base plate 32.

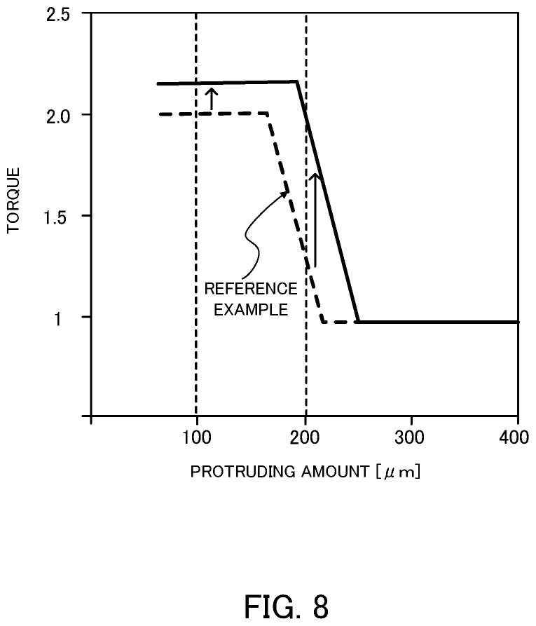

By contrast, in the semiconductor device 1, the attachment portions 24 are provided by forming the openings 24d between the side frames 21c1 and 21c2 in the frame body 21. The following describes the torque of a screw 31 used for attaching the semiconductor device 1 to the heat dissipation base plate 32, with reference to FIG. 8. FIG. 8 is a graph representing the tightening torque of a screw with respect to the protruding amount of a substrate of a semiconductor device. In FIG. 8, the horizontal axis represents the protruding amount (μm) of the substrate (heat dissipation plate 11) of the semiconductor device 1 from the rear surface thereof. The vertical axis represents the torque of the screw 31 needed for fastening using the screw 31 with respect to the protruding amount (μm). In this connection, the torque in the vertical axis is represented in a ratio to a predetermined reference value. In addition, the broken line in FIG. 8 represents the reference example of FIG. 7.

For example, in the case of the protruding amount of 100 μm, the torque of the screw 31 for attaching the semiconductor device 100 of the reference example to the heat dissipation base plate 32 is approximately 2. On the other hand, the torque of the screw 31 for attaching the semiconductor device 1 to the heat dissipation base plate 32 is approximately 2.3, which is higher.

In addition, in the case of the protruding amount of 200 μm, the torque of the screw 31 for attaching the semiconductor device 100 of the reference example to the heat dissipation base plate 32 is approximately 1.4. On the other hand, the torque of the screw 31 for attaching the semiconductor device 1 to the heat dissipation base plate 32 is approximately 2.1, which is higher.

As described above, the attachment of the semiconductor device 1 to the heat dissipation base plate 32 allows increased torque of the screw 31. That is to say, the resistance to the tightening of the screw 31 into the frame body 21 of the semiconductor device 1 is increased, as compared with the semiconductor device 100 of the reference example. In the semiconductor device 1, the openings 24d are formed between the side frames 21a1 and 21a2 and between the side frames 21c1 and 21c2 in the frame body 21 to thereby form the attachment portions 24. In addition, the reinforcing portions 25 are respectively provided in the regions formed by each side frame 21c1 and 21c2 and the corresponding one of the attachment frames 24a and 24c. Therefore, the stress generated by the tightening of the screw 31 is not concentrated at the forming places (the points 02 in FIG. 6) of the attachment portion 24 in the side frames 21c1 and 21c2 but is distributed toward the points b. Therefore, in the semiconductor device 1, cracks C occur at the points b of the side frames 21c1 and 21c2. In this connection, it has been confirmed that the resistance to the tightening of the screw 31 is increased as the curved ratio R of the reinforcing surface 25a of the reinforcing portion 25 of the attachment portion 24 becomes higher to some extent, although it is not illustrated.

In addition, it is desired that the length L2 of the reinforcing portions 25 is long in order to distribute the stress generated by the tightening of the screw 31 toward the points b of the side frames 21c1 and 21c2. However, the length L2, if too long, limits the housing area of the upper housing space 22. Therefore, the length L2 is preferably in the range of 1 to 1.5 times the length L1, inclusive, and is more preferably in the range of 1.3 to 1.5 times the length L1, inclusive.

In addition, the reinforcing portions 25 prevent the thermal stress generated between the frame body 21 and the sealing material 30 due to heat generated in the semiconductor device 1 from being concentrated at the forming places (the points 02) of the attachment portion 24 in the side frames 21c1 and 21c2. Therefore, the difference in material between the frame body 21 and the sealing material 30 does not greatly contribute to extending the cracks C.

In addition, in the attachment portion 24 of the semiconductor device 1, the opening 24d is formed between the side frames 21c1 and 21c2. Therefore, in order to remove the semiconductor device 1 fastened to the heat dissipation base plate 32 by the screws 31, the screws 31 does not need to be removed completely from the attachment portions 24. This makes it easy to remove the semiconductor device 1 from the heat dissipation base plate 32 in a short time.

The above-described semiconductor device 1 includes first and second semiconductor chips 13 and 14, a substrate including a circuit wiring pattern 12 having the first and second semiconductor chips 13 and 14 disposed on the front surface thereof and a heat dissipation plate 11, a frame body 21, and a sealing material 30. The frame body 21 is rectangular in plan view, and has side frames 21a1 and 21a2, a side frame 21b, side frames 21c1 and 21c2, and a side frame 21d that are attached to the heat dissipation plate 11 so as to surround the four sides of an upper housing space 22 in order, and the upper housing space 22 is surrounded by the side frames 21a1 and 21a2, side frame 21b, side frames 21c1 and 21c2, and side frame 21d. The sealing material 30 fills the upper housing space 22 to seal the front surface of the substrate and the first and second semiconductor chips 13 and 14. In addition, the frame body 21 has attachment portions 24 to which screws 31 are attached, on the side of the side frames 21a1 and 21a2 facing the upper housing space 22 and on the side of the side frames 21c1 and 21c2 facing the upper housing space 22.

The attachment portions 24 each include a pair of attachment frames 24a and 24c and a connecting frame 24b. In plan view, the paired attachment frames 24a and 24c respectively connect to the side frames 21a1 and 21a2 or the side frames 21c1 and 21c2, face each other with an opening 24d penetrating through the side frames 21a1 and 21a2 or side frames 21c1 and 21c2 therebetween, and extend toward the inside of the upper housing space 22 in parallel to the side frames 21b and 21d. The connecting frame 24b connects ends of the paired attachment frames 24a and 24c closest to the inside of the upper housing space 22. In addition, the frame body 21 includes reinforcing portions 25. In plan view, the reinforcing portions 25 are respectively provided in the regions formed by each of the side frames 21a1 and 21a2 and side frames 21c1 and 21c2 and the corresponding one of the paired attachment frames 24a and 24c. The reinforcing portions 25 are each in contact with the point 02 at the corner at which one of the side frames 21a1 and 21a2 and side frame 21c1 and 21c2 and the corresponding one of the paired attachment frames 24a and 24c are joined, the one of the side frames 21a1 and 21a2 and side frames 21c1 and 21c2, and the corresponding one of the paired attachment frames 24a and 24c. Therefore, the stress generated by the tightening of screws 31 is not concentrated at the forming places (the points 02 in FIG. 6) of the attachment portions 24 in the side frames 21a1 and 21c2 and the side frames 21c1 and 21c2 but is distributed toward the points b. As described above, the resistance to the tightening of the screws 31 is increased, which prevents the frame body 21 from being damaged and also prevents a reduction in the reliability of the semiconductor device 1.

In addition, the attachment portions 24 of the semiconductor device 1 are provided around the openings 24d formed between the side frames 21a1 and 21a2 and between the side frames 21c1 and 21c2. This makes it easy to remove the semiconductor device 1 from the heat dissipation base plate 32 in a short time.

(Variation 1-1)

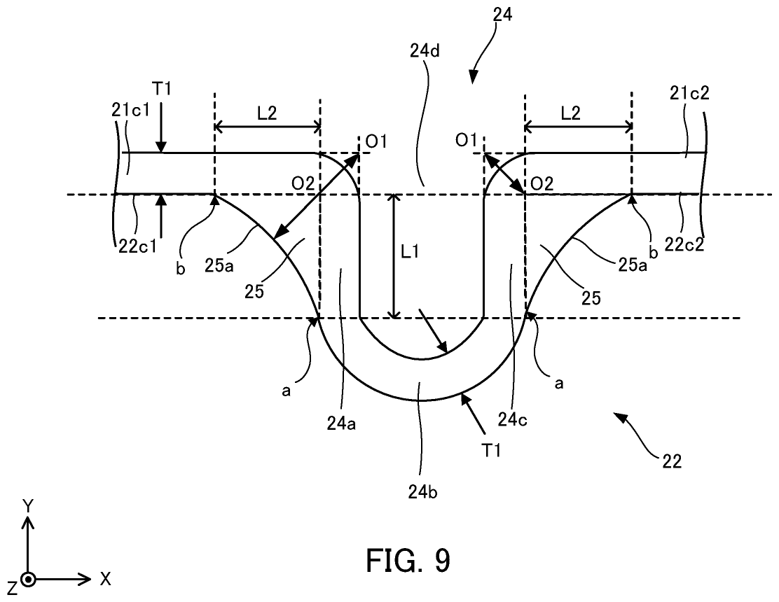

An attachment portion 24 of the semiconductor device 1 according to variation 1-1 of the first embodiment will be described with reference to FIG. 9. FIG. 9 is a plan view of an attachment portion of the semiconductor device according to the first embodiment (variation 1-1). The attachment portion 24 included in the semiconductor device 1 may be formed such that the surfaces at the outer corner points 01 formed by each side frame 21c1 and 21c2 of the attachment portion 24 of FIG. 6, which face the opening 24d, are rounded. In this configuration, when a screw 31 is inserted in the attachment portion 24 to attach the semiconductor device 1 to the heat dissipation base plate 32, the screw 31 is inserted in the opening 24d smoothly even if the screw 31 contacts the corners at the points 01. That is, it becomes easier to achieve the attachment using the screw 31.

(Variation 1-2)

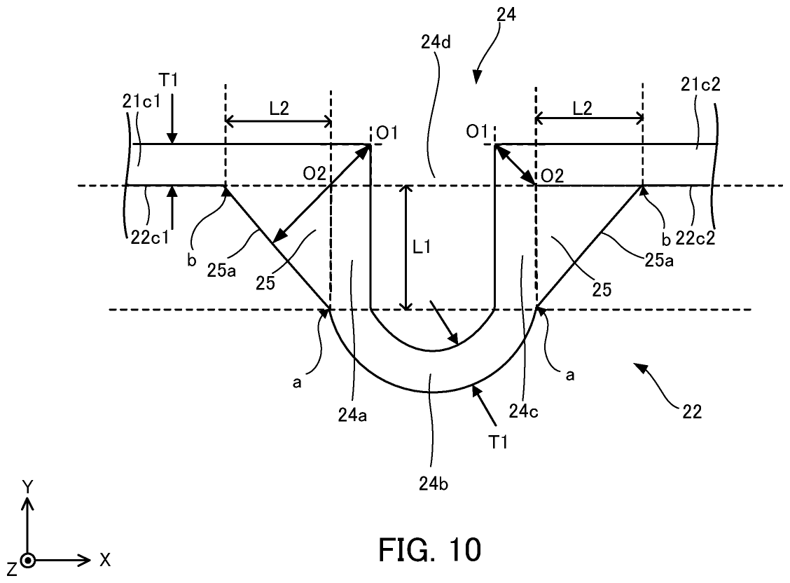

An attachment portion 24 of the semiconductor device 1 according to variation 1-2 of the first embodiment will be described with reference to FIG. 10. FIG. 10 is a plan view of an attachment portion of the semiconductor device according to the first embodiment (variation 1-2). The reinforcing surface 25a of the reinforcing portion 25 of the attachment portion 24 included in the semiconductor device 1 of variation 1-2 is formed such as to connect the points a and b that are the end points of the reinforcing portion 25, in a straight line in plan view. That is to say, the reinforcing surface 25a is tapered. This configuration is able to provide the same effects as the first embodiment as well. In addition, as in variation 1-1, the surfaces at the corner points 01 formed by each side frame 21c1 and 21c2 of the attachment portion 24, which face the opening 24d, may be rounded in variation 1-2.

The surfaces at the points b that are the connecting places of each side frame 21c1 and 21c2 and the reinforcing portion 25 may be rounded. When the semiconductor device 1 in which the upper housing space 22 is filled with the sealing material 30 operates and thus heat is generated, thermal stress is prevented from being concentrated at the points b. Thus, even if cracks have occurred at the points b of the side frames 21c1 and 21c2, the cracks are prevented from extending.

### Second Embodiment

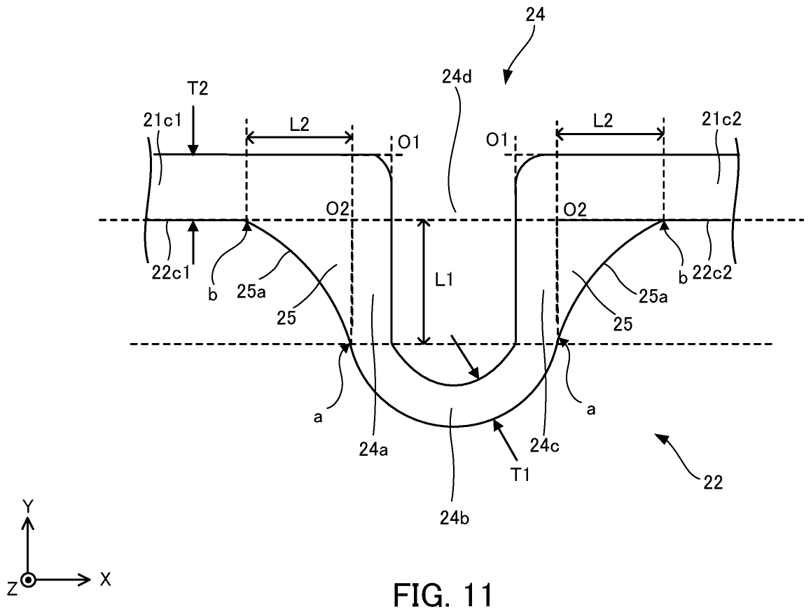

The following describes an attachment portion 24 and side frames 21c1 and 21c2 included in a semiconductor device 1 of a second embodiment with reference to FIG. 11. FIG. 11 is a plan view of an attachment portion of the semiconductor device according to the second embodiment.

In the second embodiment, the first embodiment is modified so that the thickness T2 of the side frames 21c1 and 21c2 is greater than the thickness T1 of the paired attachment frames 24a and 24c and connecting frame 24b. It has been confirmed that this case improves the resistance to the tightening of the screws 31, compared with the case of FIG. 6 (the case where the thickness of the side frames 21c1 and 21c2 is equal to the thickness of the paired attachment frames 24a and 24c and connecting frame 24b). However, the thickness T2, if too thick, limits the area of the upper housing space 22 or increases the size of the frame body 21. Therefore, the thickness T2 is preferably in the range of 1.3 to 1.5 times the thickness T1, inclusive.

In addition, the second embodiment may be further modified such that the surfaces at the corner points 01 formed by each side frame 21c1 and 21c2 of the attachment portion 24, which face the opening 24d, are rounded or the reinforcing surface 25a is tapered, as in at least one of variation 1-1 and variation 1-2.

The disclosed technique is able to improve the resistance to the tightening of screws, prevent a semiconductor device from being damaged, and thus prevent a reduction in the reliability of the semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
a substrate including the semiconductor chip on a front surface thereof;
a case that is rectangular in a plan view of the semiconductor device and includes first to fourth side frames in this order that are attached to the substrate so that the first to fourth side frames are respectively disposed at respective ones of four sides of the substrate to form a housing region therein; and
a sealing material filling the housing region to seal the front surface of the substrate and the semiconductor chip, wherein
the case further includes a first attachment portion, to which a screw is attached, on a side of the first side frame facing the housing region,
the first attachment portion includes a pair of first attachment frames extending toward an inside of the housing region in parallel to the second side frame and the fourth side frame in the plan view, and a first connecting frame connecting ends of the pair of first attachment frames at the inside of the housing region, the pair of first attachment frames connecting to the first side frame and facing each other with an opening therebetween penetrating through the first side frame in the plan view, and
the case further includes a first reinforcing portion that is provided in a first region formed by the first side frame and one of the pair of first attachment frames in the plan view, the first reinforcing portion being in contact with the first side frame, the one of the pair of first attachment frames, and a first corner at which the first side frame and the one of the pair of first attachment frames are joined in the plan view.

2. The semiconductor device according to claim 1, wherein the first connecting frame has a semicircular shape and projects toward the inside of the housing region in the plan view.

3. The semiconductor device according to claim 2, wherein the first reinforcing portion includes a first reinforcing surface connecting, in the plan view, a first end point and a second end point, the first end point being located closest to the inside of the housing region in a portion of the first reinforcing portion that is in contact with the one of the pair of attachment frames, the second end point being located closest to the second side frame or the fourth side frame in a portion of the first reinforcing portion that is in contact with the first side frame.

4. The semiconductor device according to claim 3, wherein the first reinforcing surface is a rounded surface that is convex toward the first corner in the plan view.

5. The semiconductor device according to claim 4, wherein a corner of the first side frame facing the opening has a rounded surface.

6. The semiconductor device according to claim 3, wherein the first reinforcing surface connects the first end point and the second end point in a straight line in the plan view.

7. The semiconductor device according to claim 3, wherein the first end point is located between the first corner and a position at which the one of the pair of first attachment frames and the first connecting frame are connected.

8. The semiconductor device according to claim 7, wherein the first end point is located at the position at which the one of the pair of first attachment frame and the first connecting frame are connected.

9. The semiconductor device according to claim 8, wherein a distance from the first corner to the second end point is in a range of 1 to 1.5 times a distance from the first corner to the first end point.

10. The semiconductor device according to claim 9, wherein the first side frame is equal in width to the pair of first attachment frames and the first connecting frame.

11. The semiconductor device according to claim 9, wherein the first side frame is greater in width than the pair of first attachment frames and the first connecting frame.

12. The semiconductor device according to claim 1, wherein the case is made of, as a main component, a material different from the sealing material.

13. The semiconductor device according to claim 1, wherein a rear surface of the substrate is flush with a rear surface of the case or protrudes to outside from the rear surface of the case.

14. The semiconductor device according to claim 1, wherein
the case further includes a second attachment portion to which a screw is attached, the second attachment portion being disposed on a side of the third side frame facing the housing region,
the second attachment portion includes a pair of second attachment frames extending toward the inside of the housing region in parallel to the second side frame and the fourth side frame in the plan view and a second connecting frame connecting between ends of the pair of second attachment frames at the inside of the housing region, the pair of second attachment frames connecting to the third side frame and facing each other with an opening penetrating through the third side frame therebetween in the plan view, and
the case further includes a second reinforcing portion that is provided in a second region formed by the third side frame and one of the pair of second attachment frames, the second reinforcing portion being in contact with the third side frame, the one of the pair of second attachment frames, and a second corner at which the third side frame and the one of the pair of second attachment frames are joined in the plan view.
